(19) United States
(12) Patent Application Publication
(10) Pub. No.: US 2026/0268959 A1
(43) Pub. Date: Sep. 10, 2026

(54) POWER SUPPLY CONTROL CIRCUIT AND MEMORY SYSTEM

(71) Applicant: Kioxia Corporation, Tokyo (JP)

(72) Inventor: Yoshinari NAKADA, Yokohama Kanagawa (JP)

(73) Assignee: Kioxia Corporation, Tokyo (JP)

(21) Appl. No.: 19/237,051

(22) Filed: Jun. 13, 2025

(30) Foreign Application Priority Data
Mar. 6, 2025 (JP) 2025-035609

(51) Int. Cl. G11C 11/4074; G11C 5/14; G11C 11/4072

(52) U.S. Cl. CPC G11C 11/4074; G11C 5/145; G11C 5/147; G11C 5/148; G11C 11/4072

(57) ABSTRACT

According to one embodiment, a power supply control circuit includes an electronic fuse, a first resistor, a reverse current detection circuit, and a gate control circuit. The first resistor is connected between gates of first and second field effect transistors included in the electronic fuse. In response to that a reverse current is detected, the gate control circuit supplies a gate control signal for turning off one transistor among the first and second field effect transistors to the gate of the one transistor. The one transistor is a transistor including a body diode that is forward biased when an input power supply voltage is higher than an output voltage.

### CROSS-REFERENCE TO RELATED APPLICATIONS

This application is based upon and claims the benefit of priority from Japanese Patent Application No. 2025-035609, filed Mar. 6, 2025, the entire contents of which are incorporated herein by reference.

### FIELD

Embodiments described herein relate generally to a power supply control circuit and a memory system.

### BACKGROUND

Memory systems such as solid state drives (SSDs) are used as storage devices of hosts such as servers.

When power systems are stopped due to natural disasters or failures, supply of input power supply voltages from servers to SSDs is stopped, which may cause corruption or loss of data not yet written on nonvolatile memories of the SSDs. As a countermeasure for this, power supply control circuits included in SSDs are configured to store reserve power necessary for executing power loss protection (PLP) operations. The PLP operations are operations of normally shutting down the SSDs by storing unwritten data in the nonvolatile memories, and are executed by controllers provided in the SSDs.

However, even when an instantaneous voltage drop such as noise occurs, that is, even when there is no problem despite continuity of a normal operation of an SSD because an input power supply voltage is recovered immediately, a power supply control circuit turns off an electronic fuse and stops a reverse current when the reverse current caused by the drop in the input power supply voltage is detected. Then, in a state where the electronic fuse is turned off, for example, when an output voltage of the power supply control circuit decreases to a voltage less than a certain value, the power supply control circuit instructs the controller to start a PLP operation. In this case, the SSD is shut down after a process of saving unwritten data into the nonvolatile memory using reserve power is executed.

In this way, when a reverse current caused due to the decrease in the input power supply voltage is detected despite the immediate recovery of the input power supply voltage, an unnecessary PLP operation is performed and the SSD is shut down.

As a method of suppressing such an unnecessary PLP operation, a method of inserting a Schottky barrier diode (SBD) between the power supply voltage input portion and the power supply control circuit to stop the reverse current can be used.

However, when this method is used, wasteful power continues to be consumed due to a drop in voltage by the SBD while the SSD is in a normal operation.

Accordingly, in the memory system such as the SSD, it is required to provide a new technology capable of stopping a reverse current and suppressing unnecessary activation of a PLP operation when an instantaneous voltage drop occurs.

### BRIEF DESCRIPTION OF THE DRAWINGS

FIG. 1 is a block diagram illustrating an example of a configuration of an information processing system including a memory system according to an embodiment.

FIG. 2 is a block diagram illustrating an example of a configuration of a power supply circuit included in the memory system according to the embodiment.

FIG. 3 is a flowchart illustrating an example of a procedure of basic operation of a power supply control circuit included in the power supply circuit.

FIG. 4 is a circuit diagram illustrating an example of a configuration of a power supply control circuit.

FIG. 5 is a diagram illustrating a change in each of an input power supply voltage and an output voltage of the power supply control circuit and a change in each of two gate voltages of the power supply control circuit.

FIG. 6 is a diagram illustrating an operation of switching an operation mode of the power supply control circuit from a first operation mode to a second operation mode.

FIG. 7 is a circuit diagram illustrating another example of the configuration of the power supply control circuit.

### DETAILED DESCRIPTION

Various embodiments will be described hereinafter with reference to the accompanying drawings.

In general, according to one embodiment, a power supply control circuit has an input terminal for receiving an input power supply voltage and an output terminal for outputting an output voltage. The power supply control circuit includes an electronic fuse, a first resistor, a reverse current detection circuit, and a gate control circuit. The electronic fuse is connected between the input terminal and the output terminal and includes a first field effect transistor and a second field effect transistor. The first field effect transistor and the second field effect transistor are connected to each other such that an anode of a first body diode included in the first field effect transistor and an anode of a second body diode included in the second field effect transistor face each other, or a cathode of the first body diode and a cathode of the second body diode face each other. The first resistor is connected between a gate of the first field effect transistor and a gate of the second field effect transistor. The reverse current detection circuit is configured to detect a reverse current flowing from the output terminal to the input terminal due to a drop of the input power supply voltage to a voltage lower than the output voltage. The gate control circuit is connected to a gate of one field effect transistor among the first field effect transistor and the second field effect transistor and configured to supply a gate control signal for turning off the one field effect transistor to the gate of the one field effect transistor in response to the detection of the reverse current by the reverse current detection circuit. The one field effect transistor is a field effect transistor including a body diode that is forward biased when the input power supply voltage is higher than the output voltage, among the first field effect transistor and the second field effect transistor.

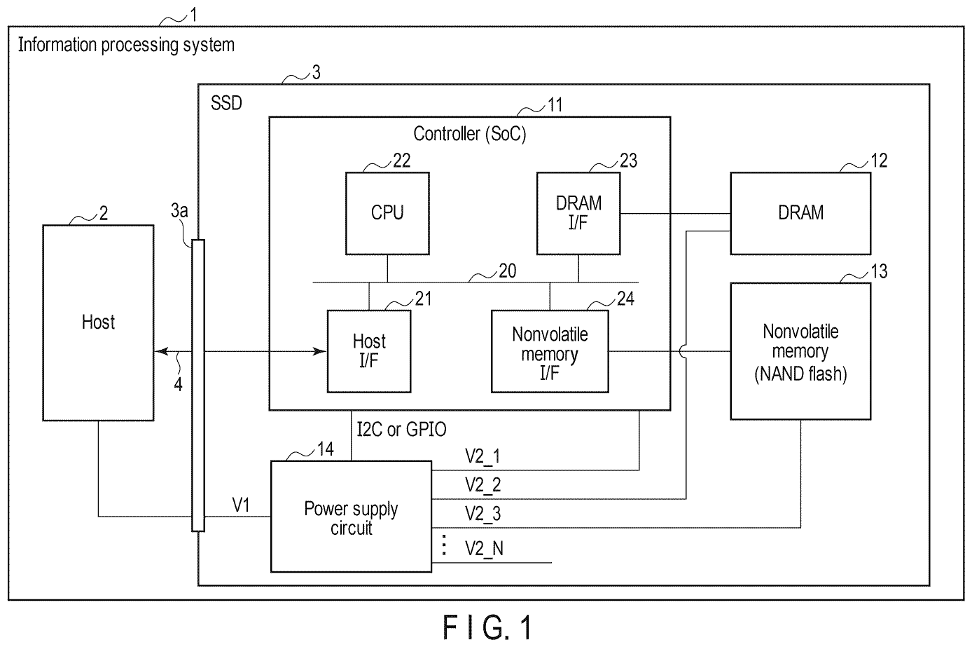

First, a configuration of an information processing system including a memory system according to an embodiment will be described. FIG. 1 is a block diagram illustrating a configuration example of an information processing system including a host and a memory system according to an embodiment. Hereinafter, it is assumed that the memory system according to the embodiment is implemented as a solid state drive (SSD) 3.

The information processing system 1 includes a host (host device) 2 and an SSD 3. The host 2 and the SSD 3 can be connected via a connector 3a.

The host 2 is an information processing device that accesses the SSD 3. The information processing device is, for example, a server computer. The host 2 transmits a write command, which is a command for writing data, to the SSD 3. The host 2 transmits a read command, which is a command for reading data, to the SSD 3.

The SSD 3 is a semiconductor storage device configured to write data to a nonvolatile memory and read data from the nonvolatile memory. As the nonvolatile memory, for example, a NAND flash memory is used. The SSD 3 executes a data write operation based on a write command received from the host 2. The SSD 3 executes a data read operation based on a read command received from the host 2.

Communication between the SSD 3 and the host 2 is executed via the bus 4. The bus 4 is a transmission path that connects the host 2 to the SSD 3. The bus 4 is, for example, a PCI express™ (PCIe™) bus. The bus 4 is a full-duplex transmission path. The full-duplex transmission path includes both a transmission path for transmitting data and an input/output (I/O) command from the host 2 to the SSD 3 and a transmission path for transmitting data and a response from the SSD 3 to the host 2. The I/O command is a command for writing data to the nonvolatile memory or reading data from the nonvolatile memory. The I/O command is, for example, a write command or a read command.

As a standard of a logical interface for connecting the host 2 and the SSD 3, for example, serial attached SCSI (SAS), serial ATA (SATA), and NVM Express™ (NVMe™) are used.

Next, components of the SSD 3 will be described. The SSD 3 includes a controller 11, a dynamic random access memory (DRAM) 12, a nonvolatile memory 13, and a power supply circuit 14.

The controller 11 is electrically connected to the nonvolatile memory 13 via a nonvolatile memory interface (nonvolatile memory I/F) 24 such as toggle NAND flash interface or an open NAND flash interface (ONFI). The controller 11 is a memory controller configured to control the nonvolatile memory 13. The controller 11 is also electrically connected to the DRAM 12 via a DRAM interface (DRAM I/F) 23.

The controller 11 is, for example, a circuit such as a system-on-a-chip (SoC). The controller 11 includes a dedicated hardware, a processor that executes a program, or a combination of the dedicated hardware and the processor. The controller 11 executes a data write operation of writing data to the nonvolatile memory 13 and a data read operation of reading data from the nonvolatile memory 13. Also, the controller 11 executes communication with the host 2 via the bus 4.

The controller 11 is further configured to perform a power loss protection (PLP) operation. The PLP operation is an operation of normally shutting down the SSD 3 by saving unwritten data into the NAND flash memory 13 using the reserve power stored in a capacitor of the power supply circuit 14.

The DRAM 12 is a volatile semiconductor memory (volatile memory). A part of the memory area of the DRAM 12 is used as, for example, a write buffer. The write buffer is a memory area for temporarily storing data to be written to the nonvolatile memory 13. The write data received from the host 2 is first stored in the write buffer of the DRAM 12 by the controller 11. Then, the write data stored in the write buffer of the DRAM 12 is written to the nonvolatile memory 13 by the controller 11.

The nonvolatile memory 13 is a nonvolatile semiconductor memory. The nonvolatile memory 13 is, for example, a NAND flash memory. The nonvolatile memory 13 may be a flash memory that has a two-dimensional structure or a flash memory that has a three-dimensional structure.

The nonvolatile memory 13 includes a plurality of blocks. Each of the plurality of blocks is a unit of a data erase operation. Each of the plurality of blocks includes a plurality of pages. Each of the plurality of pages is a unit of each of the data write operation and the data read operation. Hereinafter, the nonvolatile memory 13 is referred to as the NAND flash memory 13.

The power supply circuit 14 generates a plurality of internal power supply voltages having mutually different voltage values using a power supply voltage (voltage V1) supplied from an external device (here, the host 2) via the connector 3a. The plurality of internal power supply voltages include, for example, a power supply voltage V2_1 for driving the controller 11, a power supply voltage V2_2 for driving the DRAM 12, a power supply voltage V2_3 for driving the NAND flash memory 13, . . . , and V2_N for driving another internal device in the SSD 3.

The power supply circuit 14 includes, for example, a power supply control circuit such as a PLP circuit, and a plurality of converters. The PLP circuit is configured to store, in the capacitor, reserve power necessary for performing the PLP operation. The power supply control circuit such as a PLP circuit also has a function of communicating with the controller 11 or another circuit in the power supply circuit 14 via an inter-integrated circuit (I2C) bus or general-purpose input/output (GPIO). The converter is, for example, a DC/DC converter. Hereinafter, the converter is referred to as a DC/DC converter.

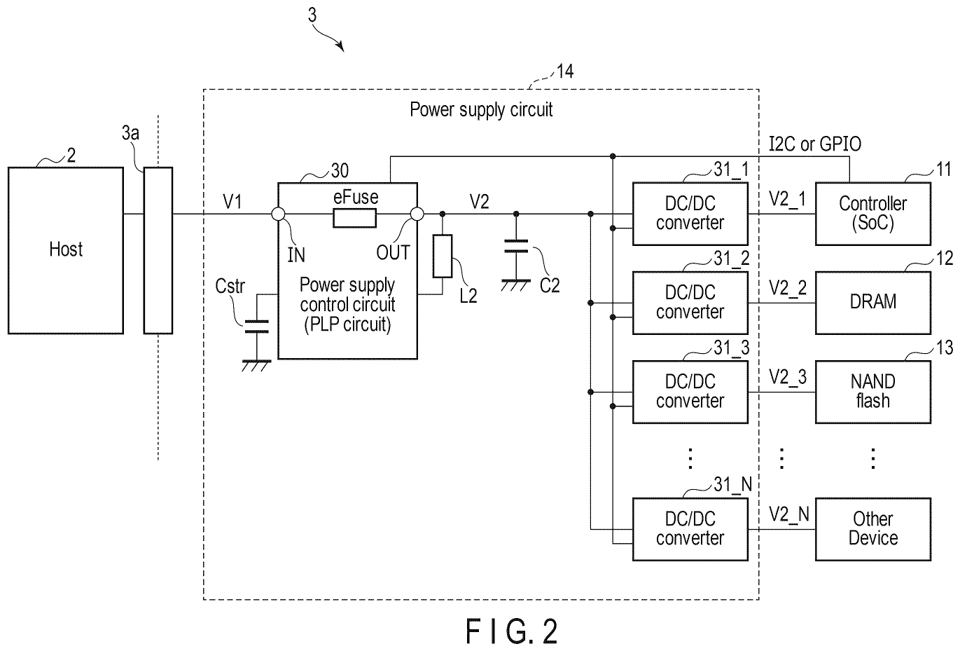

Next, a configuration of the power supply circuit 14 will be described. FIG. 2 is a block diagram illustrating an example of a configuration of the power supply circuit 14 included in the SSD 3 according to the embodiment.

The power supply circuit 14 includes a power supply control circuit 30, a PLP capacitor Cstr, an inductor L2, a capacitor C2, and a plurality of DC/DC converters 31_1 to 31_N.

The power supply control circuit 30 includes an input terminal IN for receiving an input power supply voltage (here, a voltage V1 that is a power supply voltage supplied from an external power supply (the host 2)) and an output terminal OUT for outputting an output voltage (here, the voltage V2). The power supply voltage supplied from the host 2, that is, the voltage V1, is, for example, 12 V (or 5 V). Hereinafter, it is assumed that the power supply voltage supplied from the host 2, that is, the voltage V1, is 12 V.

The power supply control circuit 30 has an electronic fuse control function and a PLP function.

The electronic fuse control function is a function of controlling an electronic fuse (eFuse) connected between the input terminal IN and the output terminal OUT to an on state or an off state. That is, when it is detected that the voltage V1 from the host 2 is a normal voltage (12 V), the power supply control circuit 30 sets the electronic fuse to an on state and accordingly outputs the voltage V1 as the voltage V2 from the output terminal OUT. While the electronic fuse is in the on state, the voltage V2 is held at substantially the same voltage as the voltage V1.

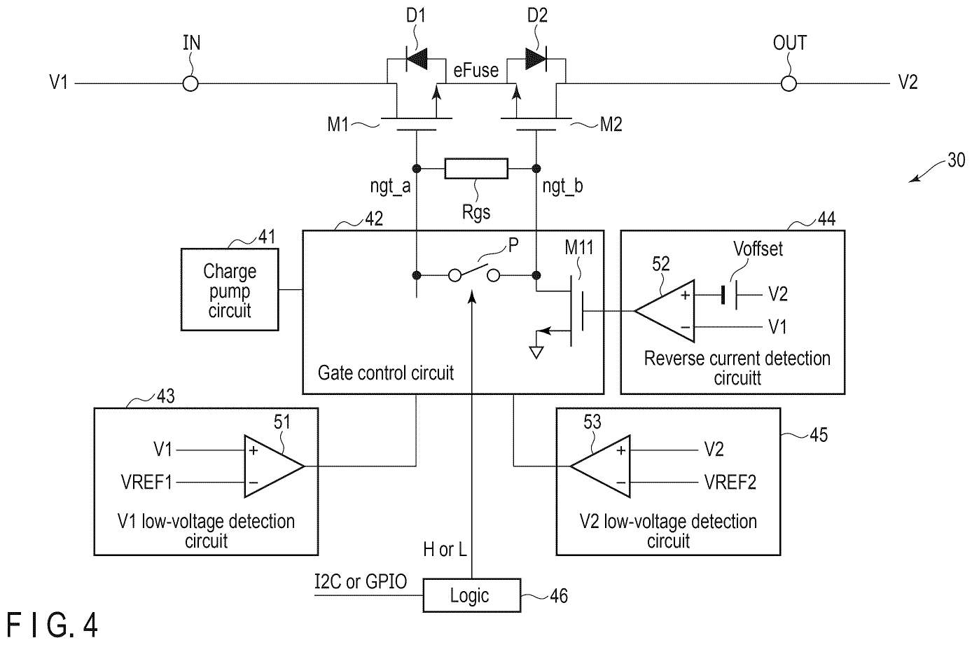

In the embodiment, the electronic fuse includes a first field effect transistor and a second field effect transistor. The first field effect transistor and the second field effect transistor are connected to each other such that an anode of a first body diode included in the first field effect transistor and an anode of a second body diode included in the second field effect transistor face each other, or a cathode of the first body diode and a cathode of the second body diode face each other. An example of a specific configuration of the electronic fuse will be described in detail in FIG. 4.

The PLP function has a function of storing the reserve power in the PLP capacitor Cstr using the voltage V2, that is, a function of charging the PLP capacitor Cstr using the voltage V2. In this case, the PLP capacitor Cstr is charged via the inductor L2 connected to the output terminal OUT. Further, the PLP function includes a function of instructing the controller 11 to execute the PLP operation and a function of supplying power to each circuit connected to the output terminal OUT using the reserve power of the PLP capacitor Cstr.

The capacitor C2 and the DC/DC converters 31_1 to 31_N are also connected to the output terminal OUT. The capacitor C2 has a role of an output capacitor for stabilizing a value of the voltage V2 when power is supplied from the PLP capacitor Cstr, and a role of an input capacitor of the DC/DC converters 31_1 to 31_N. A capacitance value of the capacitor C2 is, for example, in a range of 100 μF to 300 μF. Instead of connecting one capacitor C2 to the output terminal OUT, a plurality of capacitors that have a total capacitance value in the range of 100 μF to 300 μF may be disposed at different positions on the output terminal OUT side, for example, positions close to each of the DC/DC converters 31_1 to 31_N.

The DC/DC converter 31_1 uses the voltage V2 to generate a power supply voltage V2_1 to be supplied to the controller 11. The DC/DC converter 31_2 generates a power supply voltage V2_2 to be supplied to the DRAM 12 using the voltage V2. The DC/DC converter 31_3 uses the voltage V2 to generate a power supply voltage V2_3 to be supplied to the NAND flash memory 13. The DC/DC converter 31_N generates a power supply voltage V2_N to be supplied to another device in the SSD 3 using the voltage V2. The power supply voltages V2_1, V2_2, V2_3, . . . , and V2_N have, for example, different voltage values. Each of the power supply voltages V2_1, V2_2, V2_3, . . . , and V2_N is, for example, 3.31 V or less.

While the voltage V2 is held within a predetermined voltage range, each of the DC/DC converters 31_1 to 31_N can normally supply each of the power supply voltages V2_1 to V2_N to the corresponding device. For example, in the case of the voltage V1 of 12 V, while the voltage V2 is held in the range of 7 V (or 8 V) to 12 V, each of the DC/DC converters 31_1 to 31_N can normally supply each of the power supply voltages V2_1 to V2_N to the corresponding device.

When the controller 11 is activated by supplying the power supply voltage V2_1 to the controller 11, each of the power supply control circuit 30 and the DC/DC converters 31_1 to 31_N can communicate with the controller 11 via the I2C bus or the GPIO. Firmware executed by the controller 11 can change a setting of the power supply control circuit 30 by storing various setting values in a register of the power supply control circuit 30. Similarly, the firmware executed by the controller 11 can change a setting of any DC/DC converter by storing various setting values in a register of any DC/DC converter among the DC/DC converters 31_1 to 31_N.

Next, an operation of the power supply control circuit 30 executed when the supply of the voltage V1 from the host 2 is interrupted will be described.

When the supply of the voltage V1 from the host 2 is interrupted, the voltage V1 immediately decreases. On the other hand, since the circuit (here, the DC/DC converters 31_1 to 31_N) and the capacitor C2 are connected to the output terminal OUT of the power supply control circuit 30, the voltage V2 does not immediately decrease. Therefore, when the supply of the voltage V1 from the host 2 is interrupted, the voltage V1 becomes lower than the voltage V2, and thus a reverse current flows from the output terminal OUT to the input terminal IN. When a large reverse current flows, there is concern of the power supply control circuit 30 being broken down. Therefore, the power supply control circuit 30 includes a reverse current detection circuit. The reverse current detection circuit includes a comparator that compares the voltage V1 with the voltage V2. The reverse current detection circuit is configured to detect a reverse current using the comparator. When a reverse current is detected by the reverse current detection circuit, the power supply control circuit 30 disconnects the input terminal IN from the output terminal OUT by setting the electronic fuse to an off state to stop the reverse current. After the electronic fuse is set to the off state, the voltage V2 gradually decreases.

When the voltage V2 becomes lower than the second reference voltage VREF2 (for example, 7 V) while the electronic fuse is set to the off state, the power supply control circuit 30 causes the controller 11 to start the PLP operation. Specifically, the power supply control circuit 30 supplies power to the circuit (here, the DC/DC converters 31_1 to 31_N) connected to the output terminal OUT by using the reserve power of the capacitor Cstr, and transmits a notification indicating that the PLP operation is required to start to the controller 11 via the I2C bus or the GPIO. When this notification is received, the controller 11 starts the PLP operation. In the PLP operation, the controller 11 writes, on the NAND flash memory 13, data (unwritten data) already received from the host 2 and not yet written on the NAND flash memory 13. After the PLP operation is completed, the controller 11 shuts down the entire SSD 3.

In the embodiment, the power supply control circuit 30 is configured to stop the reverse current and not to activate the PLP operation when the lowered voltage V1 is immediately recovered to the normal voltage (12 V). That is, the power supply control circuit 30 causes the controller 11 to start the PLP operation only when the voltage V1 is not recovered to the normal voltage within a predetermined period, and causes the controller 11 to continue the normal operation when the voltage V1 is recovered to the normal voltage within the predetermined period.

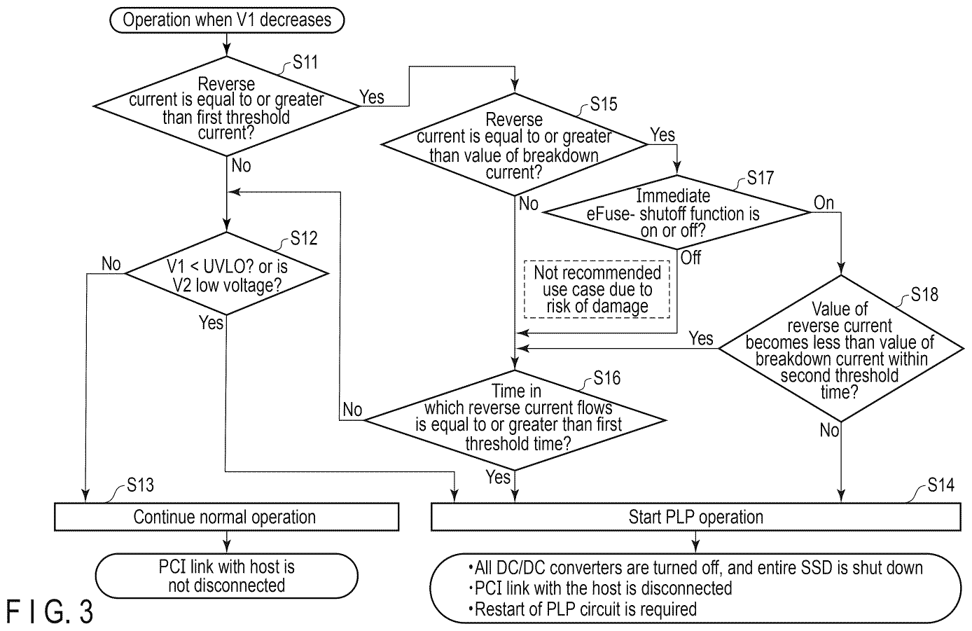

Each field effect transistor included in the electronic fuse may be broken down due to a large reverse current flowing or a reverse current continuing to flow for a predetermined time or more. Therefore, when the voltage V1 drops, the power supply control circuit 30 executes the following operation illustrated in the flowchart of FIG. 3. In the flowchart of FIG. 3, steps S11, S15, S16, and S18 mean that the comparator of the reverse current detection circuit included in the power supply control circuit 30 monitors the current.

The power supply control circuit 30 determines whether the reverse current is equal to or greater than the first threshold current (step S11). When the reverse current is less than the first threshold current (No in step S11), the power supply control circuit 30 determines whether a condition (low-voltage condition) that the voltage V1 is less than the first reference voltage or the voltage V2 is less than the second reference voltage is satisfied (step S12). The first reference voltage is set to, for example, a minimum operating voltage of the power supply control circuit 30. The minimum operating voltage is a minimum value of the input power supply voltage at which the power supply control circuit 30 can operate, and is also referred to as an undervoltage lockout (UVLO) voltage. The second reference voltage is a lower limit of a voltage range in which each of the DC/DC converters 31_1 to 31_N can normally supply each of the power supply voltages V2_1 to V2_N to the corresponding device. The second reference voltage is, for example, 7 V (or 8 V).

When the low-voltage condition is not satisfied (No in step S12), the power supply control circuit 30 causes the controller 11 to continue the normal operation (step S13). In this case, the PCI link with the host 2 is not disconnected.

When the low-voltage condition is satisfied (Yes in step S12), the power supply control circuit 30 causes the controller 11 to start the PLP operation (step S14). In step S14, the power supply control circuit 30 supplies power to the circuit (here, the DC/DC converters 31_1 to 31_N) connected to the output terminal OUT by using the reserve power of the capacitor Cstr, and transmits a notification indicating that the PLP operation is required to start to the controller 11 via the I2C bus or the GPIO. In this case, the controller 11 executes the PLP operation.

After the writing of all the unwritten data on the NAND flash memory 13 is completed in the PLP operation, the controller 11 shuts down the entire SSD 3. When the entire SSD 3 is shut down, all the DC/DC converters 31_1 to 31_N enter a non-operating state. The PCI link with the host 2 is disconnected. After the voltage V1 recovers to a normal voltage, it is necessary to restart the power supply control circuit (PLP circuit) 30 and restart the entire SSD 3.

When the value of the reverse current is equal to or greater than the first threshold current (Yes in step S11), the power supply control circuit 30 determines whether the value of the reverse current is equal to or greater than the value of the breakdown current (step S15). The value of the breakdown current is a value of a reverse current that can cause breakdown of each field effect transistor included in the electronic fuse.

When the value of the reverse current is less than the value of the breakdown current (No in step S15), the power supply control circuit 30 determines whether a time in which the reverse current flows is equal to or greater than the first threshold time (step S16). When the time in which the reverse current flows is not equal to or greater than the first threshold time (No in step S16), the power supply control circuit 30 causes the process to proceed to step S12.

When the time in which the reverse current flows is equal to or greater than the first threshold time (Yes in step S16), the power supply control circuit 30 causes the process to proceed to step S14.

When the value of the reverse current is equal to or greater than the value of the breakdown current (Yes in step S15), the power supply control circuit 30 determines whether an immediate electronic fuse shutoff function is turned on (enabled) or off (disabled) (step S17). The immediate electronic fuse shutoff function is a function of immediately turning off an electronic fuse and stopping the reverse current when the value of the reverse current is equal to or greater than the value of the breakdown current.

When the immediate electronic fuse shutoff function is turned on (enabled) (On in step S17), the power supply control circuit 30 determines whether the value of the reverse current becomes less than the value of the breakdown current within the second threshold time (step S18).

When the value of the reverse current becomes less than the value of the breakdown current within the second threshold time (Yes in step S18), the power supply control circuit 30 causes the process to proceed to step S16.

When the value of the reverse current does not become equal to or less than the value of the breakdown current within the second threshold time (No in step S18), the power supply control circuit 30 causes the process to proceed to step S14.

When the immediate electronic fuse shutoff function is turned off (disabled) (Off in step S17), the power supply control circuit 30 causes the process to proceed to step S16. Since there is a risk of breakdown of each field effect transistor, it is not recommended to turn off (disable) the immediate electronic fuse shutoff function.

By executing the foregoing operation, the power supply control circuit 30 can cause the controller 11 to start the PLP operation when the value of the reverse current does not become equal to or less than the value of the breakdown current within the first threshold time, when the reverse current flows for the first threshold time or more, or when the low voltage condition is satisfied. When the value of the reverse current becomes equal to or less than the value of the breakdown current within the second threshold time, that is, when the voltage V1 is immediately recovered to the normal voltage, the power supply control circuit 30 can cause the controller 11 to continue the normal operation.

Next, a configuration of the power supply control circuit 30 will be described. FIG. 4 is a circuit diagram illustrating an example of a configuration of the power supply control circuit 30.

The power supply control circuit 30 includes field effect transistors M1 and M2, a charge pump circuit 41, a gate control circuit 42, a V1 low-voltage detection circuit 43, a reverse current detection circuit 44, a V2 low-voltage detection circuit 45, and a logic 46.

The electronic fuse (E-fuse) includes two field effect transistors M1 and M2. Each of the field effect transistors M1 and M2 is, for example, an N-channel field effect transistor (for example, an N-channel MOSFET). Hereinafter, the field effect transistors M1 and M2 are referred to as transistors M1 and M2.

A drain of the transistor M1 is connected to the input terminal IN. A source of the transistor M1 is connected to a source of the transistor M2. A drain of the transistor M2 is connected to the output terminal OUT.

The body diode D1 included in the transistor M1 itself is a PN junction diode including an anode connected to the source of the transistor M1 and a cathode connected to the drain of the transistor M1, and is also referred to as a parasitic diode of the transistor M1.

The body diode D2 included in the transistor M2 itself is a PN junction diode including an anode connected to the source of the transistor M2 and a cathode connected to the drain of the transistor M2, and is also referred to as a parasitic diode of the transistor M2.

Here, the electronic fuse has a configuration in which the transistors M1 and M2 are connected such that the anodes of the body diodes D1 and D2 face each other. The electronic fuse may have a configuration in which the transistors M1 and M2 are connected such that the cathodes of the body diodes D1 and D2 face each other.

The charge pump circuit 41 boosts the voltage V1 to generate a gate voltage for turning on each of the transistor M1 and the transistor M2. That is, the charge pump circuit 41 generates a gate voltage equal to or higher than V1+Vf by boosting the voltage V1. Here, Vf denotes a threshold voltage of each of the transistors M1 and M2. Vf is, for example, a voltage range of 0.4 V to 3.0 V.

The gate control circuit 42 is a circuit that controls the gate voltage of each of the transistors M1 and M2.

The V1 low-voltage detection circuit 43 is an input voltage drop detection circuit configured to detect that the voltage V1 drops to a voltage lower than a first reference voltage VREF1. The first reference voltage VREF1 is the above-described UVLO voltage. The V1 low-voltage detection circuit 43 includes a comparator 51 that compares the voltage V1 with the first reference voltage VREF1 (UVLO voltage). The voltage V1 is input to a positive input terminal of the comparator 51, and the first reference voltage VREF1 (UVLO voltage) is input to a negative input terminal of the comparator 51.

The reverse current detection circuit 44 is configured to detect a reverse current flowing from the output terminal OUT to the input terminal IN due to the drop in the voltage V1 to a voltage lower than the voltage V2. The reverse current detection circuit 44 includes a comparator 52 that compares the voltage V1 with the voltage V2. A voltage value obtained by subtracting the offset voltage Voffset from the voltage V2 is input to the positive input terminal of the comparator 52, and the voltage V1 is input to the negative input terminal of the comparator 52. When the voltage V1 drops to a voltage lower than the voltage V2, specifically, when the voltage V1 becomes lower than the voltage V2 by the offset voltage Voffset or more, an output signal of the comparator 52 is changed from a low level to a high level. The relationship between the voltages V2 and V1, that is, a voltage drop (V2−V1) caused by the reverse current, is determined based on the value of the reverse current and the on-resistance of each of the transistors M1 and M2. Accordingly, by appropriately setting the offset voltage Voffset, the reverse current can be indirectly monitored by the comparator 52.

The V2 low-voltage detection circuit 45 is an output voltage drop detection circuit configured to detect that the voltage V2 drops to a voltage lower than the second reference voltage VREF2. The second reference voltage VREF2 is 7 V or 8 V as described above. The V2 low-voltage detection circuit 45 includes a comparator 53 that compares the voltage V2 with the second reference voltage VREF2. The voltage V2 is input to a positive input terminal of the comparator 53, and the second reference voltage VREF2 is input to a negative input terminal of the comparator 53.

When the voltage V1 drops during a normal operation of the SSD 3, the reverse current detection circuit 44 of the power supply control circuit 30 detects two abnormalities. The first abnormality is that the voltage V1 becomes lower than the voltage V2, and the second abnormality is that a reverse current flows from the output terminal OUT to the input terminal IN. A state in which the power supply control circuit 30 detects two abnormalities is referred to as an abnormality detection state.

Here, a power supply control circuit according to a comparative example will be considered. In the comparative example, for example, when the voltage V1 drops and a reverse current is detected by the reverse current detection circuit, the gate control circuit stops the reverse current by stopping the charge pump circuit and turning off the electronic fuse. At this time, the power supply control circuit according to the comparative example discharges from both gates of the two transistors M1 and M2 to turn off both the transistors M1 and M2, and prevents a reverse current from flowing from the output terminal OUT to the input terminal IN.

Then, when the voltage V2 becomes lower than the second reference voltage VREF2, the PLP operation is activated.

When the voltage V1 rises to a voltage higher than the voltage V2 again, the abnormality detection state by the reverse current detection circuit is released, and the charge pump circuit is driven again. In this case, since the charges at the gates of both the transistors M1 and M2 have already been discharged, it takes a relatively long time of about 0.1 ms to 1 ms to complete the re-turning-on of the electronic fuse.

When the electronic fuse is completely turned off in response to the reverse current detection, the voltage V2 becomes lower than the second reference voltage VREF2 even if the value of the reverse current becomes equal to or less than the value of the breakdown current within the second threshold time (that is, even if the lowered voltage V1 immediately recovers to a normal voltage, the voltage V2 becomes lower than the second reference voltage VREF2). As described above, when a reverse current caused due to the drop in the voltage V1 is detected despite the immediate recovery of the voltage V1 to the normal voltage, an unnecessary PLP operation is executed and the SSD 3 is shut down.

In the embodiment, the gate of the transistor M1 and the gate of the transistor M2 are separated by inserting a resistor Rgs between the gate of the transistor M1 and the gate of the transistor M2. Accordingly, when the reverse current is detected, a gate control signal for turning off the transistor M2 is supplied to the gate of the transistor M2. That is, the N-channel field effect transistor M11 is connected between the gate of the transistor M2 and the ground terminal. Therefore, when the reverse current is detected, the gate control circuit 42 lowers a gate voltage ngt_b of the transistor M2 by turning on the transistor M11.

The body diode D2 of the transistor M2 is forward biased when the voltage V1 is higher than the voltage V2. That is, the anode of the body diode D2 is connected to the input terminal IN side, and the cathode of the body diode D2 is connected to the output terminal OUT side. Accordingly, the transistor M2 including the body diode D2 contributes to the backflow prevention. Conversely, the body diode D1 of the transistor M1 is forward biased when the voltage V2 is higher than the voltage V1. Therefore, the transistor M1 including the body diode D1 does not contribute to the backflow prevention.

As described above, when the voltage V1 drops and the voltage V1 is greater than the first reference voltage VREF1 (UVLO voltage) and less than the voltage V2, the power supply control circuit 30 according to the embodiment stops the backflow from the output terminal OUT to the input terminal IN by lowering the gate voltage ngt_b of the transistor M2 in response to the detection of the reverse current. Further, since the gate voltage ngt_a of the transistor M1 is discharged via the resistor Rgs, the transistor M1 is turned off after a certain time delay.

When the voltage V1 rises to a voltage higher than the voltage V2 again while the transistor M1 is held in the on state, a current flows from the input terminal IN to the output terminal OUT through the body diode D2 of the transistor M2 in the off state in the transistor M2 until the transistor M2 is turned on again. Therefore, the voltage V2 is held in a range of a constant value (=(V1−Vfb)) and is held in a state in which the voltage V2 is higher than the second threshold voltage VREF2. Accordingly, the activation of the PLP operation due to the drop of the voltage V2 to a voltage lower than the second reference voltage VREF2 is prevented. Accordingly, despite the detection of the reverse current, the SSD 3 can continue the normal operation when the voltage V1 is recovered immediately.

Here, Vfb denotes a forward drop voltage of the body diode D2 that is in a voltage range of 0.4 V to 1.0 V.

When the reverse current is detected, the controller 11 may selectively use operation mode #1 in which both the transistors M1 and M2 are turned off, and operation mode #2 in which only the transistor M2 is turned off when the reverse current is detected. For example, a switch P is connected between the gate of the transistor M1 and the gate of the transistor M2, and the logic 46 turns on or off the switch P based on an on/off instruction from the controller 11, so that operation mode #1 and operation mode #2 can be selectively used. Details will be described below.

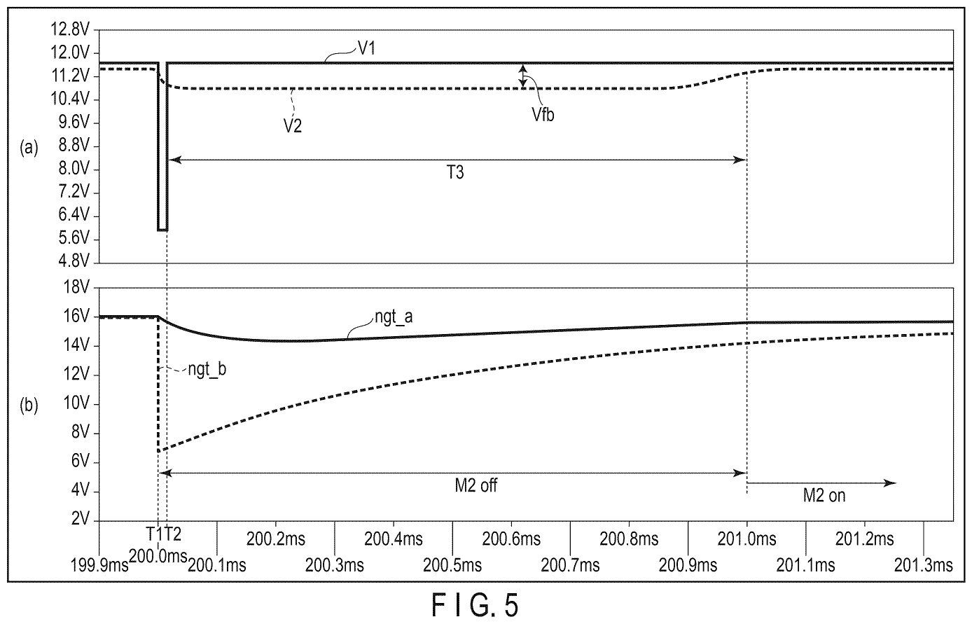

Next, an operation of the power supply control circuit 30 illustrated in FIG. 4 will be described with reference to FIG. 5. In (a) of FIG. 5, a change in each of the voltages V1 and V2 of the power supply control circuit 30 is illustrated. In (b) of FIG. 5, a change in each of two gate voltages ngt_a and ngt_b of the power supply control circuit 30 is illustrated.

The vertical axis in (a) of FIG. 5 represents a voltage, and the horizontal axis in (a) of FIG. 5 represents time. In (a) of FIG. 5, a solid line indicates the voltage V1, and a dotted line indicates voltage V2. The vertical axis in (b) of FIG. 5 represents a voltage, and the horizontal axis in (b) of FIG. 5 represents a time. In (b) of FIG. 5, a solid line indicates the gate voltage ngt_a, and a dotted line indicates the gate voltage ngt_b.

When the voltage V1 drops and the voltage V1 is greater than the first reference voltage VREF1 (UVLO voltage) and less than the voltage V2, the power supply control circuit 30 stops the backflow from the output terminal OUT to the input terminal IN by decreasing the gate voltage ngt_b of the transistor M2 in response to the reverse current detection (timing T1).

In this case, since the gate voltage ngt_a of the transistor M1 is discharged via the resistor Rgs, the transistor M1 is turned off later than the transistor M2 by a certain time. When the voltage V1 rises to a voltage higher than the voltage V2 again while M1 is held in the on state (timing T2), the abnormality detection state by the reverse current detection circuit 44 is released, and the charge pump circuit 41 is re-driven. In a period (T3) from the timing T2 until the transistor M2 is turned on again, the current flows from the input terminal IN to the output terminal OUT via the transistor M1 and the body diode D2. Therefore, since the voltage V2 is held in the range of the second threshold current (=(V1−Vfb)), the activation of the PLP operation due to the voltage V2 being lower than the second reference voltage VREF2 is prevented. Accordingly, despite the detection of the reverse current, the SSD 3 can continue the normal operation when the voltage V1 is recovered immediately.

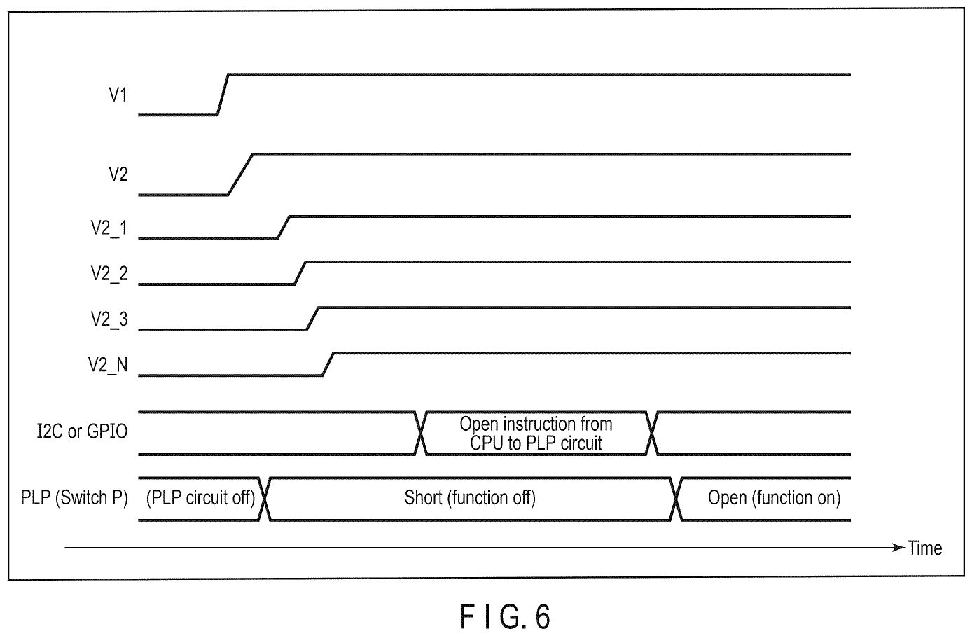

FIG. 6 is a diagram illustrating an operation of switching the operation mode of the power supply control circuit 30 from a first operation mode (mode #1) to a second operation mode (mode #2).

A default state of the switch P is, for example, the on state.

When the voltage V1 is supplied from the host 2, the power supply control circuit (PLP circuit) 30 starts an operation. The power supply control circuit 30 drives the charge pump circuit 41 and supplies the gate voltage generated by the charge pump circuit 41 to the gate of each of the transistor M1 and the transistor M2. When each of the transistor M1 and the transistor M2 is turned on, the voltage V2 rises to substantially the same voltage as the voltage V1. Then, a power supply voltage V2_1 for driving the controller 11, a power supply voltage V2_2 for driving the DRAM 12, power supply voltages V2_3 for driving the NAND flash memory 13, . . . , and V2_N for driving other internal devices in the SSD 3 are generated by the DC/DC converters 31_1 to 31_N.

The CPU 22 of the controller 11 transmits an instruction (open instruction) for turning off the switch P to the power supply control circuit (PLP circuit) 30 via the I2C bus or the GPIO. In response to reception of the open instruction, the logic 46 of the power supply control circuit (PLP circuit) 30 turns off (opens) the switch P. Accordingly, a function of turning off only the transistor M2 is turned on, and the operation mode of the power supply control circuit (PLP circuit) 30 is switched from mode #1 to mode #2.

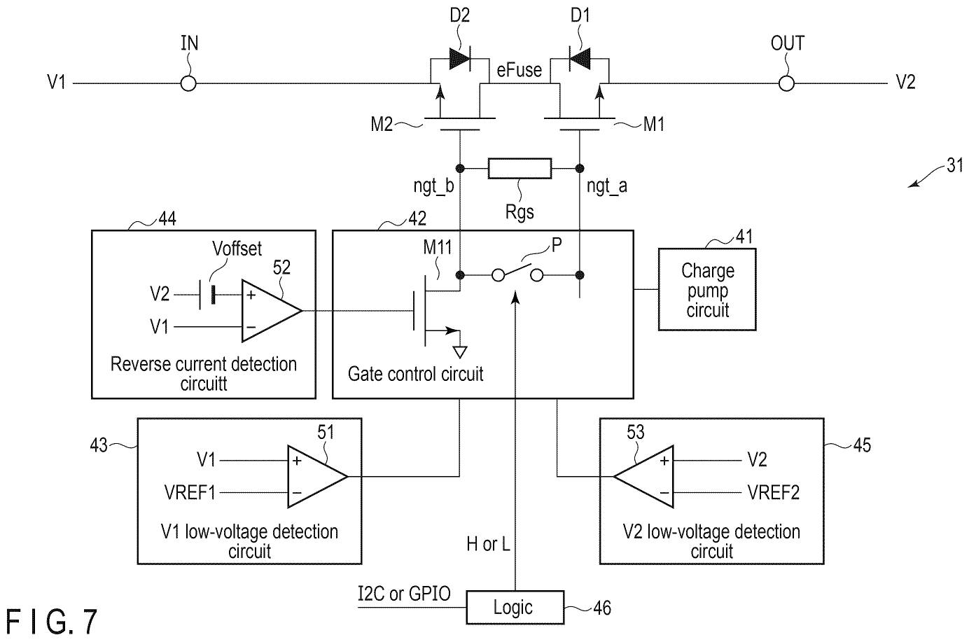

FIG. 7 is a circuit diagram illustrating the power supply control circuit 31 that is another example of the configuration of the power supply control circuit 30.

As illustrated in FIG. 7, the power supply control circuit 31 is different from the power supply control circuit 30 in that the transistors M2 and M1 are connected to each other such that the cathode of the body diode D2 faces the cathode of the body diode D1.

Specifically, the source of the transistor M2 is connected to the input terminal IN. The drain of the transistor M2 is connected to the drain of the transistor M1. The source of the transistor M1 is connected to the output terminal OUT.

The body diode D2 of the transistor M2 is forward biased when the voltage V1 is higher than the voltage V2. That is, the transistor M2 including the body diode D2 contributes to backflow prevention. Conversely, the body diode D1 of the transistor M1 is forward biased when the voltage V2 is higher than the voltage V1. Therefore, the transistor M1 including the body diode D1 does not contribute to the backflow prevention.

In this way, when the electronic fuse is configured such that the cathodes of the body diodes D1 and D2 face each other and a reverse current is detected, the gate control circuit 42 lowers only the gate voltage ngt_b of the transistor M2 that contributes to the backflow prevention.

The other configuration of the power supply control circuit 31 in the other example is the same as the configuration of the power supply control circuit 30 described with reference to FIG. 4.

As described above, according to the embodiment, the resistor Rgs is connected between the gate of the transistor M1 and the gate of the transistor M2. The gate control circuit 42 is connected to the gate of one of the transistors M1 and M2, and supplies a gate control signal for turning off the one transistor to the gate of the one transistor in response to detection of a reverse current by the reverse current detection circuit 44. Here, of the transistors M1 and M2, one transistor is a transistor (in the embodiment, the transistor M2) including a body diode (in the embodiment, the body diode D2) that is forward biased when the voltage V1 is higher than the voltage V2.

In this configuration, it is possible to prevent a reverse current from flowing. When the voltage V1 is immediately recovered to a voltage higher than the voltage V2, it is possible to flow a current from the input terminal IN to the output terminal OUT via the transistor M1 and the body diode D2. Accordingly, when the voltage V1 instantaneously drops, the reverse current can be stopped, and unnecessary activation of the PLP operation can be prevented.

The power supply control circuit 30 may not necessarily have the PLP function. In this case, the power supply control circuit 30 functions as an electronic fuse IC including the electronic fuse control function described in the embodiment. The same advantages as those of the embodiment can be obtained by providing the electronic fuse IC that has the electronic fuse control function described in the embodiment at a front stage of a normal power supply control circuit (PLP circuit).

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A power supply control circuit that includes an input terminal for receiving an input power supply voltage and an output terminal for outputting an output voltage, the power supply control circuit comprising:
an electronic fuse connected between the input terminal and the output terminal and including a first field effect transistor and a second field effect transistor, the first effect transistor and the second field effect transistor being connected to each other such that an anode of a first body diode included in the first field effect transistor and an anode of a second body diode included in the second field effect transistor face each other, or a cathode of the first body diode and a cathode of the second body diode face each other;
a first resistor connected between a gate of the first field effect transistor and a gate of the second field effect transistor;
a reverse current detection circuit configured to detect a reverse current flowing from the output terminal to the input terminal due to a drop of the input power supply voltage to a voltage lower than the output voltage; and
a gate control circuit connected to a gate of one field effect transistor among the first field effect transistor and the second field effect transistor and configured to supply a gate control signal for turning off the one field effect transistor to the gate of the one field effect transistor in response to the detection of the reverse current by the reverse current detection circuit,
the one field effect transistor being a field effect transistor including a body diode that is forward biased when the input power supply voltage is higher than the output voltage, among the first field effect transistor and the second field effect transistor.

2. The power supply control circuit according to claim 1,
wherein the reverse current detection circuit includes a first comparator configured to compare the input power supply voltage with the output voltage.

3. The power supply control circuit according to claim 2, further comprising an input voltage drop detection circuit configured to detect that the input power supply voltage drops to a voltage lower than a first reference voltage,
wherein the input voltage drop detection circuit includes a second comparator configured to compare the input power supply voltage with the first reference voltage.

4. The power supply control circuit according to claim 3, further comprising an output voltage drop detection circuit configured to detect that the output voltage drops to a voltage lower than a second reference voltage,
wherein the output voltage drop detection circuit includes a third comparator configured to compare the output voltage with the second reference voltage.

5. The power supply control circuit according to claim 1, wherein
each of the first field effect transistor and the second field effect transistor is an N-channel field effect transistor, and
the gate control circuit includes a third field effect transistor connected between the gate of the one field effect transistor and a ground terminal and further configured to turn on the third field effect transistor in response to the detection of the reverse current by the reverse current detection circuit.

6. The power supply control circuit according to claim 5, further comprising a charge pump circuit configured to generate a gate voltage for turning on each of the first field effect transistor and the second field effect transistor by boosting the input power supply voltage,
wherein the gate control circuit is further configured to supply the gate voltage generated by the charge pump circuit to the gate of each of the first field effect transistor and the second field effect transistor while the input power supply voltage is equal to or greater than the output voltage.

7. The power supply control circuit according to claim 4, wherein
the power supply control circuit is configured to:
store reserve power in a first capacitor by using the output voltage; and
in response to that a drop of the output voltage to a voltage equal to or less than the second reference voltage is detected by the output voltage drop detection circuit after supplying the gate control signal for turning off the one field effect transistor to the gate of the one field effect transistor, supply power to a circuit connected to the output terminal by using the reserve power of the first capacitor.

8. The power supply control circuit according to claim 4, wherein
the power supply control circuit is configured to:
when the reverse current detection circuit detects the reverse current and the reverse current is equal to or larger than a second threshold current,
in response to elapse of a second threshold time, transmit a first notification to a controller.

9. The power supply control circuit according to claim 8,
wherein, when the reverse current is less than the second threshold current, the second comparator compares the input power supply voltage with the first reference voltage, and the third comparator compares the output voltage with the second reference voltage, and
wherein, when the input power supply voltage is lower than the first reference voltage as a result of the comparison by the second comparator or when the output voltage is lower than the second reference voltage as a result of the comparison by the third comparator, the power supply control circuit transmits the first notification to the controller.

10. The power supply control circuit according to claim 9,
wherein, when the input power supply voltage is higher than the first reference voltage as a result of the comparison by the second comparator or when the output voltage is higher than the second reference voltage as a result of the comparison by the third comparator, the power supply control circuit does not transmit the first notification to the controller.

11. A memory system comprising:
a nonvolatile memory;
a controller electrically connected to the nonvolatile memory and configured to control the nonvolatile memory;
a first converter configured to generate a first power supply voltage to be supplied to the nonvolatile memory;
a second converter configured to generate a second power supply voltage to be supplied to the controller; and
a power supply control circuit having an input terminal configured to receive an input power supply voltage supplied from an external power supply and an output terminal connected to each of the first converter and the second converter and configured to output an output voltage,
the power supply control circuit including:
an electronic fuse connected between the input terminal and the output terminal and including a first field effect transistor and a second field effect transistor, the first field effect transistor and the second field effect transistor being connected to each other such that an anode of a first body diode included in the first field effect transistor and an anode of a second body diode included in the second field effect transistor face each other, or a cathode of the first body diode and a cathode of the second body diode face each other;
a first resistor connected between a gate of the first field effect transistor and a gate of the second field effect transistor;
a reverse current detection circuit configured to detect a reverse current flowing from the output terminal to the input terminal due to a drop of the input power supply voltage to a voltage lower than the output voltage; and
a gate control circuit connected to a gate of one field effect transistor among the first field effect transistor and the second field effect transistor and configured to supply a gate control signal for turning off the one field effect transistor to the gate of the one field effect transistor in response to the detection of the reverse current by the reverse current detection circuit, and
the one field effect transistor being a field effect transistor including a body diode that is forward biased when the input power supply voltage is higher than the output voltage, among the first field effect transistor and the second field effect transistor.

12. The memory system according to claim 11, wherein the reverse current detection circuit includes a first comparator configured to compare the input power supply voltage with the output voltage.

13. The memory system according to claim 12,
wherein the power supply control circuit further includes an input voltage drop detection circuit configured to detect that the input power supply voltage drops to a voltage lower than a first reference voltage, and
wherein the input voltage drop detection circuit includes a second comparator configured to compare the input power supply voltage with the first reference voltage.

14. The memory system according to claim 13,
wherein the power supply control circuit further includes an output voltage drop detection circuit configured to detect that the output voltage drops to a voltage lower than a second reference voltage, and
wherein the output voltage drop detection circuit includes a third comparator configured to compare the output voltage with the second reference voltage.

15. The memory system according to claim 11,
wherein each of the first field effect transistor and the second field effect transistor is an N-channel field effect transistor, and
wherein the gate control circuit includes a third field effect transistor connected between the gate of the one field effect transistor and a ground terminal, and the gate control circuit is further configured to turn on the third field effect transistor in response to the detection of the reverse current by the reverse current detection circuit.

16. The memory system according to claim 15,
wherein the power supply control circuit further includes a charge pump circuit configured to generate a gate voltage for turning on each of the first field effect transistor and the second field effect transistor by boosting the input power supply voltage, and
wherein the gate control circuit is further configured to supply the gate voltage generated by the charge pump circuit to the gate of each of the first field effect transistor and the second field effect transistor while the input power supply voltage is equal to or greater than the output voltage.

17. The memory system according to claim 14, wherein
the power supply control circuit is configured to:
store reserve power in a first capacitor by using the output voltage; and
in response to that a drop of the output voltage to a voltage equal to or less than the second reference voltage is detected by the output voltage drop detection circuit after supplying the gate control signal for turning off the one field effect transistor to the gate of the one field effect transistor, supply power to each of the first converter and the second converter by using the reserve power of the first capacitor, and transmit a first notification to the controller,
the controller is connectable to a host, and
the controller is further configured to:
in response to receiving the first notification, execute a power loss protection operation to write first data to the nonvolatile memory, the first data being data that is already received from the host and is unwritten to the nonvolatile memory.

18. The memory system according to claim 17, further comprising:
a volatile memory; and
a third converter connected to the output terminal and configured to generate a third power supply voltage to be supplied to the volatile memory,
wherein the controller is configured to:
in the power loss protection operation, read the first data from the volatile memory and write the read first data to the nonvolatile memory.
